(19) United States
(12) Patent Application Publication
(10) Pub. No.: US 2015/0307345 A1
(43) Pub. Date: Oct. 29, 2015

(54) ELECTRONIC DEVICE AND MANUFACTURING METHOD OF THE SAME

(71) Applicant: KABUSHIKI KAISHA TOSHIBA, Tokyo (JP)

(72) Inventors: Kei OBARA, Kawasaki Kanagawa (JP); Tsuyoshi HIRAYU, Yokohama Kanagawa (JP); Kiyonori IGARASHI, Kitakami Iwate (JP)

(73) Assignee: KABUSHIKI KAISHA TOSHIBA, Tokyo (JP)

(21) Appl. No.: 14/642,474

(22) Filed: Mar. 9, 2015

(30) Foreign Application Priority Data
Apr. 28, 2014 (JP) 2014-092989

(51) Int. Cl. B81B 7/00; B81C 1/00

(52) U.S. Cl. CPC B81B 7/0041; B81C 1/00293; B81C 2203/0136

(57) ABSTRACT

According to one embodiment, an electronic device includes a MEMS element formed on an underlying region, and a stack film covering the MEMS element and forming a cavity part inside, wherein the stack film includes a first layer having a hole, a second layer provided on the first layer and covering the hole, a third layer provided on the second layer and formed of an oxide, and a fourth layer provided on the third layer and formed of a nitride.

### CROSS-REFERENCE TO RELATED APPLICATIONS

This application is based upon and claims the benefit of priority from Japanese Patent Application No. 2014-092989, filed Apr. 28, 2014, the entire contents of which are incorporated herein by reference.

### FIELD

Embodiments described herein relate generally to an electronic device and a manufacturing method of the same.

### BACKGROUND

MEMS elements include mechanically movable parts and need a cavity structure to accommodate such parts therein. In general, a stack film covering the MEMS element is formed for such a cavity structure. In general, a silicon nitride film which is moistureproof is used for the uppermost layer of the stack film.

However, electronic devices including MEMS elements covered with stack films having better performance are desired.

### BRIEF DESCRIPTION OF THE DRAWINGS

FIG. 1 is a cross-sectional view which schematically shows part of a manufacturing method of an electronic device of an embodiment.

FIG. 2 is a cross-sectional view which schematically shows part of a manufacturing method of an electronic device of the embodiment.

FIG. 3 is a cross-sectional view which schematically shows part of a manufacturing method of an electronic device of the embodiment.

FIG. 4 is a cross-sectional view which schematically shows part of a manufacturing method of an electronic device of the embodiment.

FIG. 5 is a cross-sectional view which schematically shows part of a manufacturing method of an electronic device of the embodiment.

### DETAILED DESCRIPTION

In general, according to one embodiment, an electronic device includes: a MEMS element formed on an underlying region; and a stack film covering the MEMS element and forming a cavity part inside, wherein the stack film includes a first layer having a hole, a second layer provided on the first layer and covering the hole, a third layer provided on the second layer and formed of an oxide, and a fourth layer provided on the third layer and formed of a nitride.

Hereinafter, embodiments are explained with reference to accompanying drawings.

FIG. 5 is a cross-sectional view which schematically shows the structure of an electronic device of an embodiment.

Underlying region 10 includes a semiconductor substrate, transistor, lines and interlayer insulating film. On the underlying region 10, an insulating film 12 and MEMS element 20 are formed.

In the present embodiment, the MEMS element 20 is a variable capacitor. The MEMS element (variable capacitor) 20 includes a lower electrode 22, upper electrode 24, and support member 26. Specifically, the capacitance of the variable capacitor varies depending on a distance between the lower electrode (fixed electrode) 22 and the upper electrode (movable electrode) 24. For example, voltage applied between the lower electrode 22 and upper electrode 24 produces electrostatic attraction therebetween which varies the distance between the lower electrode 22 and the upper electrode 24, and thus the capacitance varies. Note that the lower electrode 22 and the upper electrode 24 may be formed of, for example, aluminum (Al).

The MEMS element 20 is covered with a stack film 30. The stack film 30 functions as a protective film which protects the MEMS element 20. The stack film 30 is formed in a thin film dome shape and a cavity part 40 is formed therein. That is, the stack film 30 covering the MEMS element 20 forms a cavity structure. The cavity structure allows the MEMS element 20 to mechanically vary. Such a structure having the stack film 30 covering the MEMS element (thin film dome) formed on a semiconductor substrate (semiconductor wafer) is referred to as a wafer level package (WLP). The cavity part 40 is kept in a vacuum atmosphere or a dry atmosphere. Therefore, deterioration of the lower electrode 22 and upper electrode 24 due to moisture or the like can be prevented.

The stack film (protective film) 30 includes, as described below, first layer 32, second layer 34, third layer 36, and fourth layer 38.

First layer 32 is formed of an inorganic material such as oxide and has a plurality of holes 32a. For example, the oxide contains silicon. Specifically, the first layer 32 may be a silicon oxide film. The holes 32a are used to form the cavity structure by etching a sacrificial layer, as explained later.

On the first layer 32, a second layer 34 is provided. The second layer 34 is formed of an organic material such as resin. Specifically, the resin may be polyimide. The second layer 34 covers and fills the holes 32a. That is, part of the second layer 34 fills at least a part of the holes 32a. The second layer 34 can pass a harmful gas inside the cavity part 40 to adjust the atmosphere in the cavity part 40. Therefore, the second layer 34 has greater gas permeability than the first layer 32.

On the second layer 34, the third layer 36 is provided. The third layer 36 is used as a buffer. That is, since the fourth layer 38 (explained later) does not have good step coverage, the third layer 36 which is interposed between the second layer 34 and the fourth layer 38 functions as a buffer film for the fourth layer 38. The third layer 36 has better step coverage than the fourth layer 38, and thus functions as a good buffer film.

The third layer 36 is formed of an oxide. For example, the oxide contains silicon. Specifically, the third layer 36 is a silicon oxide film. The oxide film used in the third layer 36 can achieve good step coverage. Especially, silicon oxide based on a material of tetraethoxysilane (TEOS), that is, TEOS silicon oxide can achieve better step coverage. Note that the third layer 36 has less gas permeability than the second layer 34.

On the third layer 36, the fourth layer 38 is provided. The fourth layer 38 is a moistureproof film. That is, since the third layer 36 does not have good moistureproofing, the fourth layer 38 which has better moistureproofing than the third layer 36 is formed for better moistureproofing as a whole. Therefore, the fourth layer 38 has less gas permeability than the third layer 36.

The fourth layer 38 is formed of a nitride. For example, the nitride may contain silicon. Specifically, the fourth layer 38 is a silicon nitride film. The fourth layer 38 formed of a nitride can achieve good moistureproofing. Especially, a silicon nitride has very small gas permeability. Even when the silicon nitride film has a thickness less than 1 μm, the gas permeability can be disregarded.

Note that the thickness of the fourth layer 38 should preferably be greater than that of the third layer 36, and should be four times as large or more. If the third layer is thicker, a difference between the stress of the third layer and the stress of the fourth layer deforms the thin film dome and the reliability of the MEMS element may probably be lowered. Thus, the fourth layer should be thicker than the third layer, preferably four times as thick or more. Thereby, the third layer fully functions as a buffer film reducing deformation of the thin film dome. Thus, the reliability of the MEMS element can be maintained. For example, the third layer 36 has a thickness of approximately 0.5 μm and the fourth layer 38 has a thickness of approximately 4.5 μm.

An hole is provided through the underlying region 10, third layer 36, and fourth layer 38. A copper line 50 including a via is formed within the hole and on the fourth layer 38.

As can be understood from the above, the third layer 36 formed of an oxide is interposed between the second layer 34 and the fourth layer 38. The film formed of an oxide generally has good coverage. Therefore, the film formed of oxide used as the third layer 36 can achieve good coverage as a whole even if the fourth layer 38 does not have good coverage. Especially, an oxide containing silicon can ensure the achievement of good coverage.

Furthermore, the fourth layer 38 formed of a nitride is formed on the third layer 36. The film of nitride generally exerts good moistureproofing. Therefore, the film formed of nitride used as the fourth layer 38 can achieve good moistureproofing as a whole even if the third layer 36 does not have good moistureproofing. Especially, a nitride containing silicon can ensure the achievement of good moistureproofing.

As can be understood from the above, the present embodiment can achieve an electronic device including a MEMS element covered with stack film having good moistureproofing and coverage.

Note that, in the present embodiment, the first layer 32 includes a first part 32b formed on the underlying region 10 directly contacting thereto and surrounding the MEMS element 20. Furthermore, the second layer 34 includes a second part 34b formed on the first part 32b of the first layer 32. Furthermore, the third layer 36 covers a first corner C1 formed of the upper surface of the first part 32b and the side surface of the second part 34b. The third layer 36 has a second corner C2 which is based on the first corner C1. The fourth layer 38 covers the second corner C2.

Given that there is not a third layer 36 between the second layer 34 and the fourth layer 38, and the fourth layer 38 is formed directly on the second layer 34, the following problem may occur. That is, the fourth layer 38 formed of a nitride may achieve good moistureproofing but not a good coverage. Thus, cracks may occur on the fourth layer 38 in the proximity to the above-explained first corner C1. Specifically, cracks may occur in the fourth layer 38 by etching for forming the cooper line 50. Such cracks lower the reliability of the MEMS element significantly.

In the present embodiment, the third layer 36 formed of an oxide with good coverage is formed between the second layer 34 and the fourth layer 38. The third layer 36 functions as a buffer for the fourth layer. As a result, a problem as above can be prevented and the reliability of the MEMS element 20 can be improved.

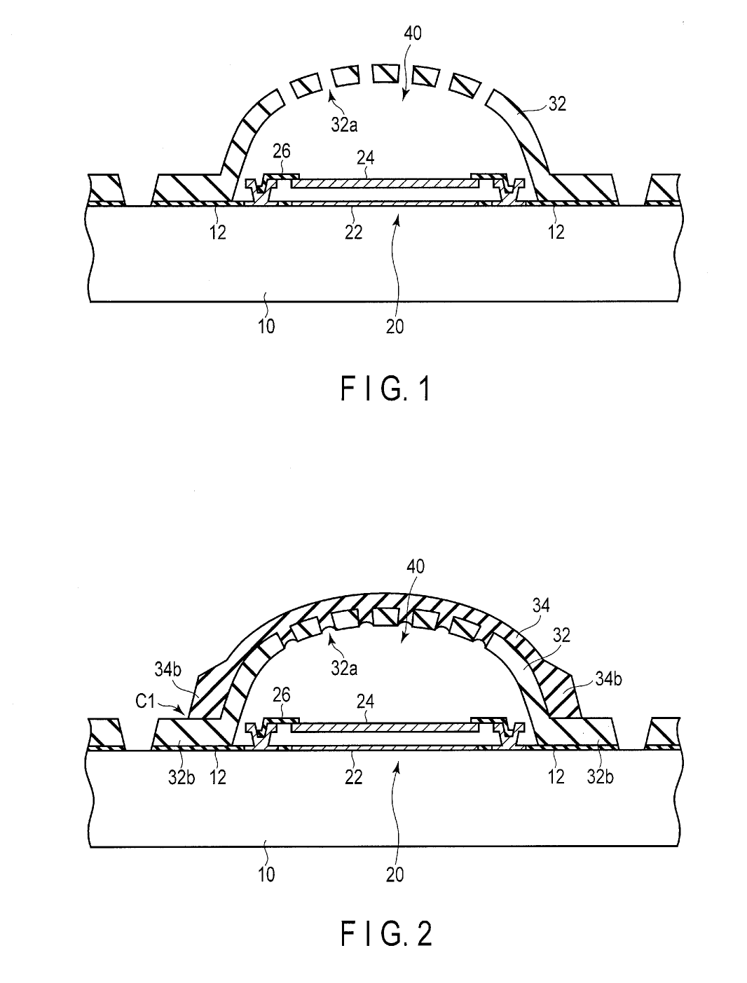

FIGS. 1 to 5 are cross-sectional views which schematically show the manufacturing method of the electronic device of the embodiment.

First, as shown in FIG. 1, the insulating film 12 and the MEMS element 20 are formed on the underlying region 10. Then, a sacrificial film (not shown) is formed to cover the MEMS element 20. Furthermore, the first layer 32 having a plurality of holes 32a is formed on the sacrificial film using an oxide. Specifically, a silicon oxide is used for the first layer 32 and then, a plurality of holes 32a are formed in the first layer 32. Moreover, an opening is formed at the part where the via of copper line 50 is formed by removing the first layer 32 partly. Then, the sacrificial film is etched by supplying an etching agent through the holes 32a to remove the sacrificial film. Thereby, the cavity part 40 is created inside the first layer 32.

Next, as shown in FIG. 2, the second layer 34 to cover the holes 32a is formed on the first layer 32 using resin. Specifically, polyimide is used as the resin to form the second layer 34. Furthermore, the second layer 34 outside the area in which the stack film is formed (dome forming area) is removed. Thereby, the first corner C1 is formed of the upper surface of the first part 32b of the first layer 32 and the side surface of the second part 34b of the second layer 34.

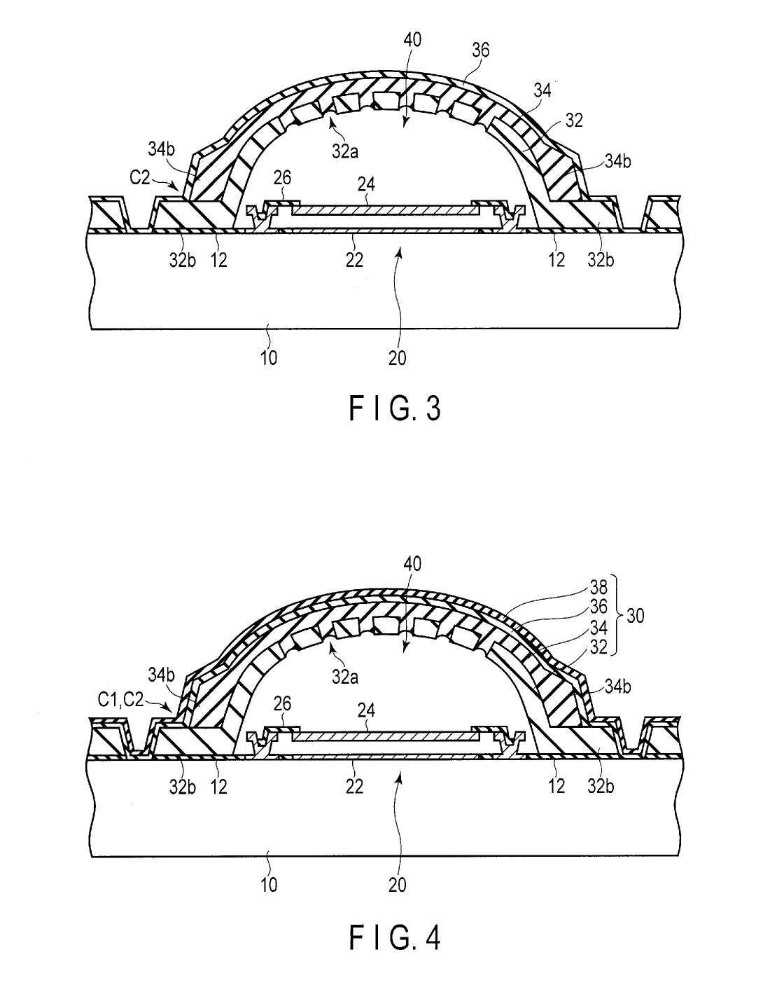

Next, as shown in FIG. 3, the third layer 36 is formed on the second layer 34 using an oxide. Specifically, the third layer 36 is formed of a silicon oxide. Specifically, the third layer 36 is formed of TEOS using chemical vapor deposition (CVD). The second corner C2 is formed in the third layer 36 based on the first corner C1.

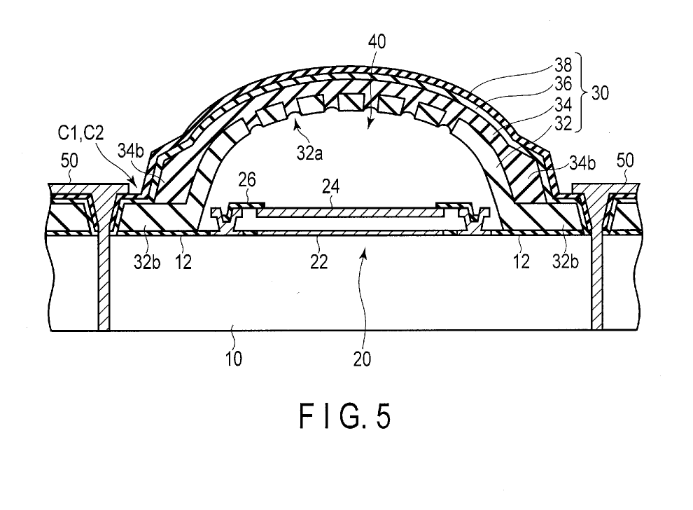

Next, as shown in FIG. 4, the fourth layer 38 is formed on the third layer 36 using a nitride. Specifically, the fourth layer 38 is formed of a silicon nitride using the CVD. The fourth layer 38 covers the second corner C2.

Through the above, the stack film 30 covering the MEMS element 20 and forming the cavity part 40 inside thereof can be manufactured.

Then, as shown in FIG. 5, the hole for via is formed through the underlying region 10, third layer 36, and fourth layer 38. Furthermore, the copper line 50 including via is formed within the hole and on the fourth layer 38. Thereby, the structure shown in FIG. 5 can be achieved.

With the manufacturing method of the present embodiment, the third layer 36 formed of an oxide for good buffer performance (for better coverage) is formed on the second layer 34, and the fourth layer 38 formed of a nitride for good moistureproofing is formed on the third layer 36. Thus, cracks on the fourth layer 38 can be prevented effectively. Thus, the manufacturing method of the present embodiment can achieve an electronic device including a MEMS element covered with a stack film having good moistureproofing and coverage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a MEMS element formed on an underlying region; and
a stack film covering the MEMS element and forming a cavity part inside,
wherein the stack film includes
a first layer having a hole,
a second layer provided on the first layer and covering the hole,
a third layer provided on the second layer and formed of an oxide, and
a fourth layer provided on the third layer and formed of a nitride.

2. The electronic device of claim 1, wherein the oxide contains silicon.

3. The electronic device of claim 1, wherein the oxide is a TEOS silicon oxide.

4. The electronic device of claim 1, wherein the third layer is a buffer film, and the fourth layer is thicker than the third layer.

5. The electronic device of claim 1, wherein the nitride contains silicon.

6. The electronic device of claim 1, wherein the fourth layer is a moistureproof film.

7. The electronic device of claim 1, wherein the second layer is formed of an organic material.

8. The electronic device of claim 1, wherein the first layer is formed of an inorganic material.

9. The electronic device of claim 1, wherein
the first layer includes a first part formed on the underlying region and surrounding the MEMS element,
the second layer includes a second part formed on the first part, and
the third layer covers a first corner formed by an upper surface of the first part and a side surface of the second part.

10. The electronic device of claim 9, wherein
the third layer has a second corner based on the first corner, and
the fourth layer covers the second corner.

11. The electronic device of claim 1, wherein the MEMS element is a variable capacitor.

12. A manufacturing method of an electronic device, comprising:
forming a MEMS element on an underlying region; and
forming a stack film covering the MEMS element, the stack film forming a cavity part inside,
wherein forming the stack film includes
forming a first layer having a hole,
forming a second layer covering the hole on the first layer,
forming a third layer formed of an oxide on the second layer, and
forming a fourth layer formed of a nitride on the third layer.

13. The method of claim 12, wherein the oxide contains silicon.

14. The method of claim 12, wherein the oxide is a TEOS silicon oxide.

15. The method of claim 12, wherein the third layer is a buffer film.

16. The method of claim 12, wherein the nitride contains silicon.

17. The method of claim 12, wherein the fourth layer is a moistureproof film.
